(19) United States
(12) Patent Application Publication
(10) Pub. No.: US 2025/0113600 A1
(43) Pub. Date: Apr. 3, 2025

(54) METAL GATE CUT WITH REDUCED OXIDATION AND PARASITIC CAPACITANCE

(71) Applicant: Intel Corporation, Santa Clara, CA (US)

(72) Inventors: Yulia Gotlib, Hillsboro, OR (US); Matthew J. Prince, Portland, OR (US); Sachin S. Vaidya, Portland, OR (US); Ying Zhou, Portland, OR (US); Xiaoye Qin, Portland, OR (US); Ryan Pearce, Beaverton, OR (US); Andrew Arnold, Hillsboro, OR (US); Chiao-Ti Huang, Portland, OR (US)

(21) Appl. No.: 18/477,947

(22) Filed: Sep. 29, 2023

(51) Int. Cl. H01L 27/092; H01L 29/06; H01L 29/423; H01L 29/775; H01L 29/786

(52) U.S. Cl. CPC H10D 84/85; H10D 30/43; H10D 30/6735; H10D 30/6757; H10D 62/121

(57) ABSTRACT

Techniques are provided herein to form semiconductor devices that include one or more gate cuts having an improved liner structure to prevent oxidation of the gate electrode. A semiconductor device includes a gate structure around or otherwise on a semiconductor region. The gate structure may be interrupted, for example, between two transistors with a gate cut that extends through an entire thickness of the gate structure and includes dielectric material to electrically isolate the portions of the gate structure on either side of the gate cut. In an example, the gate cut includes a silicon nitride dielectric liner with a higher percentage of Si—H bonds compared to Si—N bonds at an interface between the dielectric liner and the gate structure. The liner may also include a higher percentage of Si—N bonds compared to Si—H bonds at an interface between the dielectric liner and a dielectric fill on the dielectric liner.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, the formation of certain device structures used to isolate adjacent transistors becomes challenging. Accordingly, there remain a number of non-trivial challenges with respect to forming semiconductor devices.

### BRIEF DESCRIPTION OF THE DRAWINGS

FIGS. 1A and 1B are cross-sectional and plan views, respectively, of some semiconductor devices that illustrate a gate cut between devices having a structure configured to reduce oxidation and parasitic capacitance, in accordance with an embodiment of the present disclosure.

FIGS. 2A-2I are cross-sectional views that illustrate various stages in an example process for forming semiconductor devices that have a gate cut with a structure configured to reduce oxidation and parasitic capacitance, in accordance with some embodiments of the present disclosure.

FIG. 3 is a cross-sectional view of semiconductor devices having a gate cut with a structure configured to reduce oxidation and parasitic capacitance, and a conductive via passing through the gate cut, in accordance with some embodiments of the present disclosure.

FIG. 4 illustrates a cross-sectional view of a chip package containing one or more semiconductor dies, in accordance with some embodiments of the present disclosure.

FIG. 5 is a flowchart of a fabrication process for semiconductor devices having a structure configured to reduce oxidation and parasitic capacitance, in accordance with an embodiment of the present disclosure.

FIG. 6 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include one or more gate cuts having a structure configured to prevent or otherwise reduce oxidation of the gate electrode as well as parasitic capacitance. The techniques can be used in any number of integrated circuit applications and are particularly useful with respect to device layer transistors, such as finFETs or gate-all-around transistors (e.g., ribbonFETs and nanowire FETs) or forksheet transistors (e.g., nanosheet FETs). In an example, a semiconductor device includes a gate structure around or otherwise on a semiconductor region (also referred to as a channel region). The semiconductor region can be, for example, a fin of semiconductor material that extends from a source region to a drain region, or one or more nanowires or nanoribbons or nanosheets of semiconductor material that extend from a source region to a drain region. The gate structure includes a gate dielectric (e.g., high-k gate dielectric material) and a gate electrode (e.g., conductive material such as workfunction material and/or gate fill metal). The gate structure may be interrupted, for example, between two transistors with a gate cut that extends through an entire thickness of the gate structure and includes dielectric material to electrically isolate the portions of the gate structure on either side of the gate cut. In an example, the gate cut includes a dielectric liner and a dielectric fill on the dielectric liner, with the dielectric fill having a lower dielectric constant compared to the liner. The inclusion of low-k dielectric fill material reduces the parasitic capacitance between adjacent conductive layers around or within the gate cut. To prevent or otherwise reduce oxidation of the gate electrode, the dielectric liner may include silicon nitride and be configured with a higher percentage of silicon-hydrogen (Si—H) bonds compared to silicon-nitrogen (Si—N) bonds at an interface between the dielectric liner and the gate electrode. The liner may also include a higher percentage of Si—N bonds compared to Si—H bonds at an interface between the dielectric liner and the dielectric fill. More generally, the liner may include a reduced amount of metal-oxygen bonds at the interface between the gate cut and the adjacent gate electrode, relative to a conventional configuration. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Example structures like gate cuts are used in integrated circuit design to isolate gate structures from one another. Such gate cuts may be relatively thin and are thus filled with a robust high-k dielectric material (e.g., a material with a dielectric constant of 6.5 or greater, such as silicon nitride). But this can lead to high parasitic capacitance between the conductive gate electrode on either side of the gate cut. Using an oxygen-containing dielectric material to fill a gate cut structure can help to reduce such parasitic capacitance. However, deposition of oxygen-containing dielectric materials implicates oxidation risk of the gate electrode. Indeed, even use of a standard silicon nitride plasma exposes the gate electrode to oxidation. Also, deposition of oxygen-containing dielectric materials includes ion flux. Such factors can cause shifting in electrical properties of the underlying material(s). Also, oxygen-rich dielectric materials may not be robust enough to withstand erosion caused by, for example, downstream processing and planarization. A dielectric liner using a high-k material can be formed first in an effort to protect the gate electrode from oxidation, but thin liners do not offer enough protection and thicker liners increase the effective dielectric constant, thus increasing the parasitic capacitance.

Thus, and in accordance with an embodiment of the present disclosure, techniques are provided herein to form gate cuts through a metal gate structure that include a structure configured to reduce oxidation and parasitic capacitance. In some embodiments, a metal gate cut includes a dielectric liner along edges of the metal gate cut that includes a high-k material (e.g., material with a dielectric constant greater than that of silicon dioxide which has a dielectric constant of 3.9, such as dielectrics having a dielectric constant greater than or equal to 6.5). The dielectric liner may include, for example, a conformal deposition of silicon nitride. Since the dielectric liner is along the edges of the gate cut, it may contact the gate electrode on either side of the gate cut. The metal gate cut also includes a dielectric fill on the dielectric liner and within an inner portion of the gate cut. According to some embodiments, the dielectric fill includes a medium-to-low-k material (e.g., material with a dielectric constant less than or equal to 4.5). Silicon dioxide or flowable silicon dioxide or porous silicon dioxide may be used for the dielectric fill, to provide a few examples.

According to some embodiments, the dielectric liner includes silicon and nitrogen deposited using an argon-only plasma (e.g., no nitrogen plasma) during the initial deposition cycles (e.g., first three to ten cycles) and then introducing nitrogen plasma thereafter, such that the silicon nitride layer is formed on the gate electrode surface with a higher percentage of silicon-hydrogen (Si—H) bonds compared to silicon-nitrogen (Si—N) bonds. These bonds may be detected by observing a higher percentage of hydrogen atoms compared to nitrogen atoms at the interface between the gate electrode and the dielectric liner. This is in contrast to deposition techniques that always include nitrogen plasma when depositing a layer of silicon nitride. The increase in the percentage of Si—H bonds at the interface with the gate electrode provides enhanced protection of the gate electrode from oxidation even when using a relatively thin dielectric liner. For example, a relatively thin layer of silicon nitride having the higher percentage of Si—H bonds compared to Si—N bonds (e.g., deposited using an argon-only plasma) may be between 10 Å and 15 Å thick, which can be formed during the initial (e.g., several) cycles of argon-only plasma assisted silicon nitride deposition. Nitrogen plasma may be introduced into the deposition environment afterwards to deposit, for example, another silicon nitride layer or phase having a higher percentage of Si—N bonds compared to Si—H bonds, or to produce a decreasing gradient of Si—H bonds from the interface between the dielectric liner structure and the gate electrode to the interface between the dielectric liner structure and the dielectric fill. These bonds may be detected by observing a higher percentage of nitrogen atoms compared to hydrogen atoms at the interface between the dielectric liner and the dielectric fill. In any case, the total thickness of the dielectric liner from one interface to the other is relatively thin, and in some example cases may be less than 5 nm or between about 2 nm and about 3 nm. A benefit of having such a relatively thin liner is that the remaining volume to be filled with oxide can be relatively larger, which may garner better device performance (e.g., no, or lower threshold voltage shift and faster switching speed). In some examples, for instance, the ratio of nitride-based liner to oxide-based fill within the overall volume of the gate cut is about 20:80 or lower, such as 10:90 or 5:95, meaning that about 80% to 95% of the gate cut volume can be oxide-based fill (e.g., low-k dielectric fill), with the remaining volume of about 5% to 20% being occupied by the liner. Other examples may have a different liner:fill ratio.

According to an embodiment, an integrated circuit includes a semiconductor device having a semiconductor region extending in a first direction from a source or drain region and a gate structure extending in a second direction over the semiconductor region, and a dielectric structure adjacent to the semiconductor region and extending across the gate structure in the first direction and through an entire thickness of the gate structure in a third direction. The dielectric structure includes a dielectric layer along edges of the dielectric structure and a dielectric fill on the dielectric layer. The dielectric layer includes a higher percentage of hydrogen compared to nitrogen at an interface between the dielectric layer and the gate structure. In some such examples, a step-based or gradual transition from Si—H bonds (near the interface between the dielectric layer and the gate structure) to Si—N bonds (near the interface between the dielectric layer and the dielectric fill portion of the dielectric structure) within the dielectric layer may be implemented, for instance, via a bi-layer or other multi-layer liner structure, or a bi-phase or other multi-phase liner structure, or a graded liner structure.

According to an embodiment, an integrated circuit includes a first semiconductor device having a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, and a dielectric structure extending in the first direction between the first gate structure and the second gate structure and through an entire thickness of the first and second gate structures in a third direction. The dielectric structure includes a dielectric layer along edges of the dielectric structure, and a dielectric fill on the dielectric layer. The dielectric layer includes a higher percentage of hydrogen atoms compared to nitrogen atoms at an interface between the dielectric layer and the first gate structure and at an interface between the dielectric layer and the second gate structure.

According to another embodiment, a method of forming an integrated circuit includes forming a fin comprising semiconductor material, the fin extending above a substrate and extending in a first direction; forming a gate electrode extending over the semiconductor material in a second direction different from the first direction; forming a recess extending in a third direction through an entire thickness of the gate electrode adjacent to the fin; forming a dielectric layer within the recess such that the dielectric layer includes a higher percentage of Si—H bonds compared to Si—N bonds at an interface between the dielectric layer and the gate electrode; and forming a dielectric fill within a remaining volume of the recess and on the dielectric layer.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, implantation-doped regions of the fin structure or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may be used to qualitatively (or quantitatively) show a higher percentage of Si—H bonds (or hydrogen) compared to Si—N bonds (or nitrogen) at an interface between the dielectric liner of a gate cut and an adjacent gate electrode. Atom probe tomography (APT) and/or X-ray photoelectron spectroscopy (XPS) can be used to show a reduced amount of metal-oxygen bonds at the interface between the dielectric liner of the gate cut and the adjacent gate electrode. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

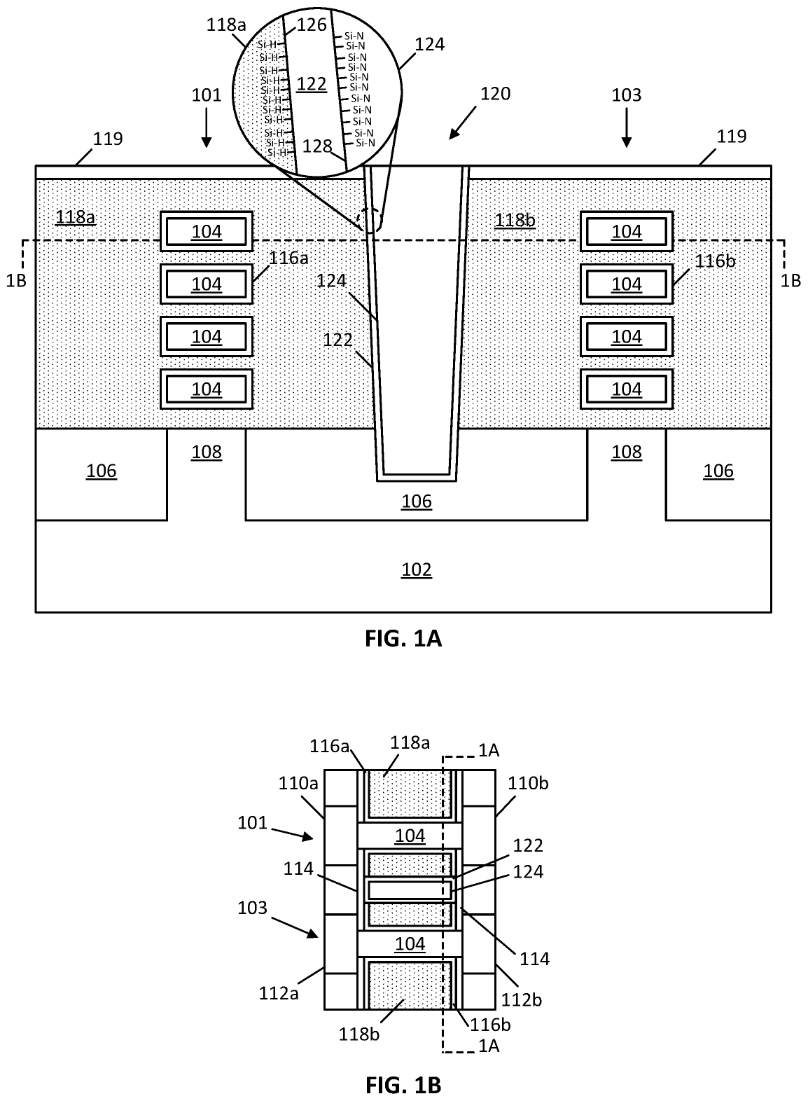

FIG. 1A is a cross-sectional view taken across two example semiconductor devices 101 and 103, according to an embodiment of the present disclosure. FIG. 1B is a top-down cross-section view of the adjacent semiconductor devices 101 and 103 taken across the dashed line 1B-1B depicted in FIG. 1A, and FIG. 1A illustrates the cross-section taken across the dashed line 1A-1A depicted in FIG. 1B. It should be noted that some of the material layers (such as gate cap 119) are not visible in the top-down view of FIG. 1B, given the location of the depicted cross-section. Each of semiconductor devices 101 and 103 may be non-planar metal oxide semiconductor (MOS) transistors, such as tri-gate (e.g., finFET) or gate-all-around (GAA) transistors, although other transistor topologies and types could also benefit from the gate cut techniques and structures provided herein. The illustrated example embodiments herein use the GAA structure. Semiconductor devices 101 and 103 represent a portion of an integrated circuit that may contain any number of similar semiconductor devices.

As can be seen, semiconductor devices 101 and 103 are formed on a substrate 102. Any number of semiconductor devices can be formed on substrate 102, but two are used here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some example embodiments, a lower portion of (or all of) substrate 102 is removed and replaced with one or more backside interconnect layers to form backside signal and power routing.

Each of semiconductor devices 101 and 103 includes one or more nanoribbons 104 that extend parallel to one another along a direction between a source region and a drain region (e.g., a first direction into and out of the page in the cross-section view of FIG. 1A). Nanoribbons 104 are one example of semiconductor regions or semiconductor bodies that extend between source and drain regions. The term nanoribbon may also encompass other similar shapes such as nanowires or nanosheets. The semiconductor material of nanoribbons 104 may be formed from substrate 102. In some embodiments, semiconductor devices 101 and 103 may each include semiconductor regions in the shape of fins that can be, for example, native to substrate 102 (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of the illustrated nanoribbons 104 during a gate forming process where one type of the alternating layers is selectively etched away so as to liberate the other type of alternating layers within the channel region, so that a gate-all-around (GAA) process can then be carried out. Again, the alternating layers can be blanket deposited and then etched into fins or deposited into fin-shaped trenches, according to some examples.

As can further be seen, adjacent semiconductor devices are separated by a dielectric fill 106 that may include silicon dioxide. Dielectric fill 106 provides shallow trench isolation (STI) between any adjacent semiconductor devices, and adjacent subfin regions 108. Dielectric fill 106 can be any suitable dielectric material, such as silicon dioxide, aluminum oxide, or silicon oxycarbonitride.

Semiconductor devices 101 and 103 each include a subfin region 108, in this example. According to some embodiments, subfin region 108 comprises the same semiconductor material as substrate 102 and is adjacent to dielectric fill 106. According to some embodiments, nanoribbons 104 (or other semiconductor bodies) extend between a source and a drain region in the first direction to provide an active region for a transistor (e.g., the semiconductor region beneath the gate). The source and drain regions are not shown in the cross-section of FIG. 1A, but are seen in the top-down view of FIG. 1B where nanoribbons 104 of semiconductor device 101 extend between a first source or drain region 110a and a second source or drain region 110b (similarly, the nanoribbons 104 of semiconductor device 103 extend between a first source or drain region 112a and a second source or drain region 112b). FIG. 1B also illustrates spacer structures 114 that extend around the ends of nanoribbons 104 and along sidewalls of the gate structures between spacer structures 114. Spacer structures 114 may include a dielectric material, such as silicon nitride.

According to some embodiments, the source and drain regions are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. In an example, for instance, one transistor is a p-type MOS (PMOS) transistor, and the other transistor is an n-type MOS (NMOS) transistor. Any number of source and drain configurations and materials can be used.

According to some embodiments, a first gate structure extends over nanoribbons 104 of semiconductor device 101 along a second direction across the page while a second gate structure extends over nanoribbons 104 of semiconductor device 103 along the second direction. The second direction may be orthogonal to the first direction. Each gate structure includes a respective gate dielectric 116a/116b and a gate electrode 118a/118b. Gate dielectric 116a/116b represents any number of dielectric layers present between nanoribbons 104 and gate electrode 118a/118b. Gate dielectric 116a/116b may also be present on the surfaces of other structures within the gate trench, such as on subfin region 108. Gate dielectric 116a/116b may include any suitable gate dielectric material(s). In some embodiments, gate dielectric 116a/116b includes a layer of native oxide material (e.g., silicon dioxide) on the nanoribbons or other semiconductor regions making up the channel region of the devices, and a layer of high-K dielectric material (e.g., hafnium oxide) on the native oxide.

Gate electrode 118a/118b may represent any number of conductive layers, such as any metal, metal alloy, or doped polysilicon layers. In some embodiments, gate electrode 118a/118b includes one or more workfunction metals around nanoribbons 104. In some embodiments, one of semiconductor devices 101 and 103 is a p-channel device that include a workfunction metal having titanium around its nanoribbons 104 and the other semiconductor device is an n-channel device that includes a workfunction metal having tungsten around its nanoribbons 104. Gate electrode 118a/118b may also include a fill metal or other conductive material (e.g., tungsten, ruthenium, molybdenum, cobalt) around the workfunction metals to provide the whole gate electrode structure. In some embodiments, a gate cap 119 may be formed over gate electrode 118a/118b to protect the underlying material during processing. Gate cap 119 may be any suitable dielectric material, such as silicon nitride.

According to some embodiments, adjacent gate structures may be separated along the second direction (e.g., across the page) by a gate cut 120, which acts like a dielectric barrier or wall between gate structures. Gate cut 120 extends vertically (e.g., in a third direction) through at least an entire thickness of the adjacent gate structure. In some embodiments, gate cut 120 also extends through an entire thickness of dielectric fill 106. According to some embodiments, gate cut 120 is formed from various dielectric materials. For example, gate cut 120 includes a dielectric liner 122 along an outer edge of gate cut 120 and a dielectric fill 124 on dielectric liner 122 and within an inner portion of gate cut 120. According to some embodiments, dielectric liner 122 includes a high-k dielectric material, such as silicon nitride, and dielectric fill 124 includes a medium-k or low-k dielectric material (e.g., a dielectric having a dielectric constant of about 4.5 or less), such as silicon dioxide, porous silicon dioxide, or flowable oxide. Dielectric fill 124 may also include one or more airgaps or voids, which may further lower the dielectric constant of gate cut 120. Gate cut 120 may have a top width along the second direction between about 40 nm and about 50 nm.

According to some embodiments, dielectric liner 122 is formed using an argon-only plasma environment (at least initially) such that a first interface 126 between dielectric liner 122 and gate electrode 118a/118b includes a higher percentage of Si—H bonds (e.g., higher percentage of hydrogen atoms) compared to Si—N bonds (e.g., higher percentage of nitrogen atoms) as seen in the blown-out image. In some such cases, the argon-only plasma environment transitions to a nitrogen-based plasma such that at a second interface 128 between dielectric liner 122 and dielectric fill 124, dielectric liner 122 includes a higher percentage of Si—N bonds compared to Si—H bonds. This may be accomplished in several different ways. For example, dielectric liner 122 may be initially deposited in an argon-only plasma environment and then nitrogen plasma may be slowly introduced and into the environment to generate a decreasing gradient of Si—H bonds from first interface 126 to second interface 128 and a corresponding increasing gradient of Si—N bonds from first interface 126 to second interface 128. In another example, a first sublayer or phase having the higher percentage of Si—H bonds compared to Si—N bonds may be deposited using an argon-only plasma, and a second sublayer or phase may be deposited on the first sublayer or phase having the higher percentage of Si—N bonds compared to Si—H bonds using a plasma that contains both argon and nitrogen. The two sublayers or phases may collectively form dielectric liner 122. Any number of sublayers or phases may be deposited with different levels of nitrogen plasma to form a stack of sublayers that are represented by dielectric liner 122. The transition from being rich in Si—H bonds to being rich in Si—N bonds may occur gradually or in a more severe or discrete stepped manner. The severity of a given step can vary from one example to the next, depending on factors such as the number of steps between the first interface 126 and the second interface 128.

Gate cut 120 also extends in the first direction as seen in FIG. 1B such that it cuts across at least the entire width of the gate trench. According to some embodiments, gate cut 120 may also extend further past spacer structures 114. In some examples, gate cut 120 extends across more than one gate trench in the first direction (e.g., cutting through more than one gate structure running parallel along the second direction).

### Fabrication Methodology

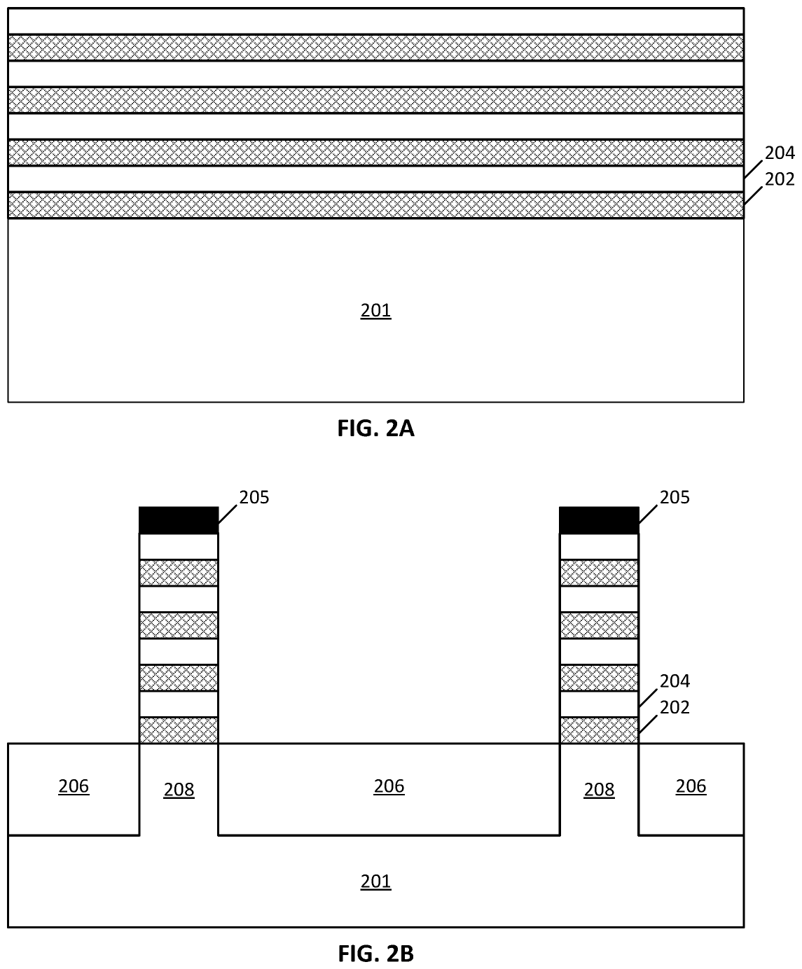

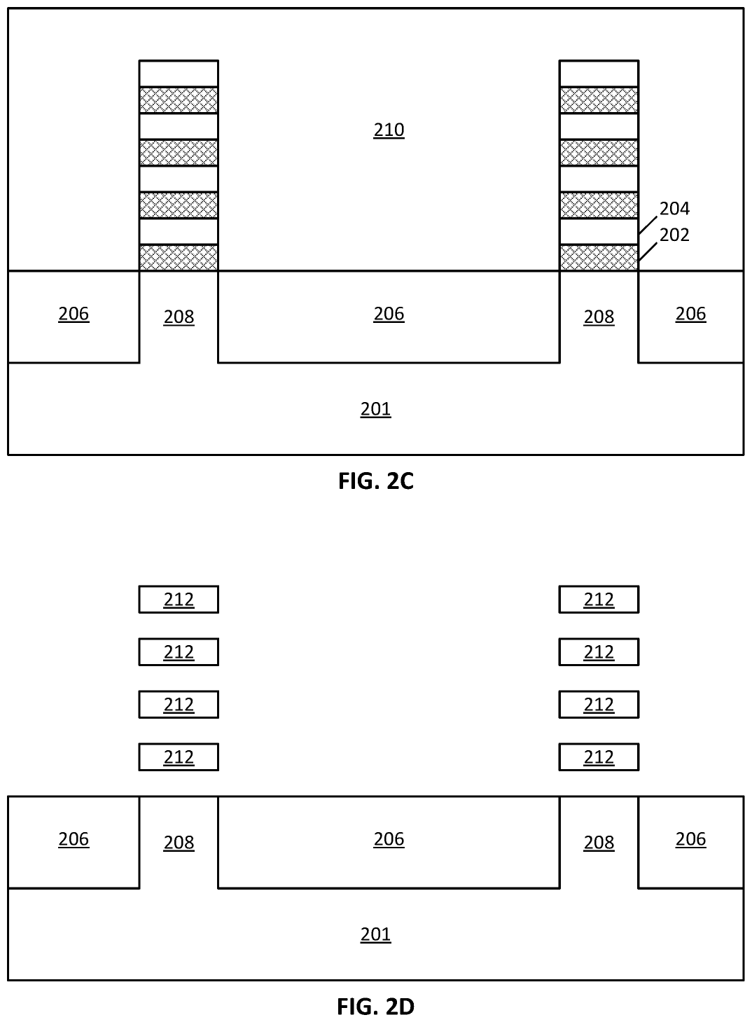

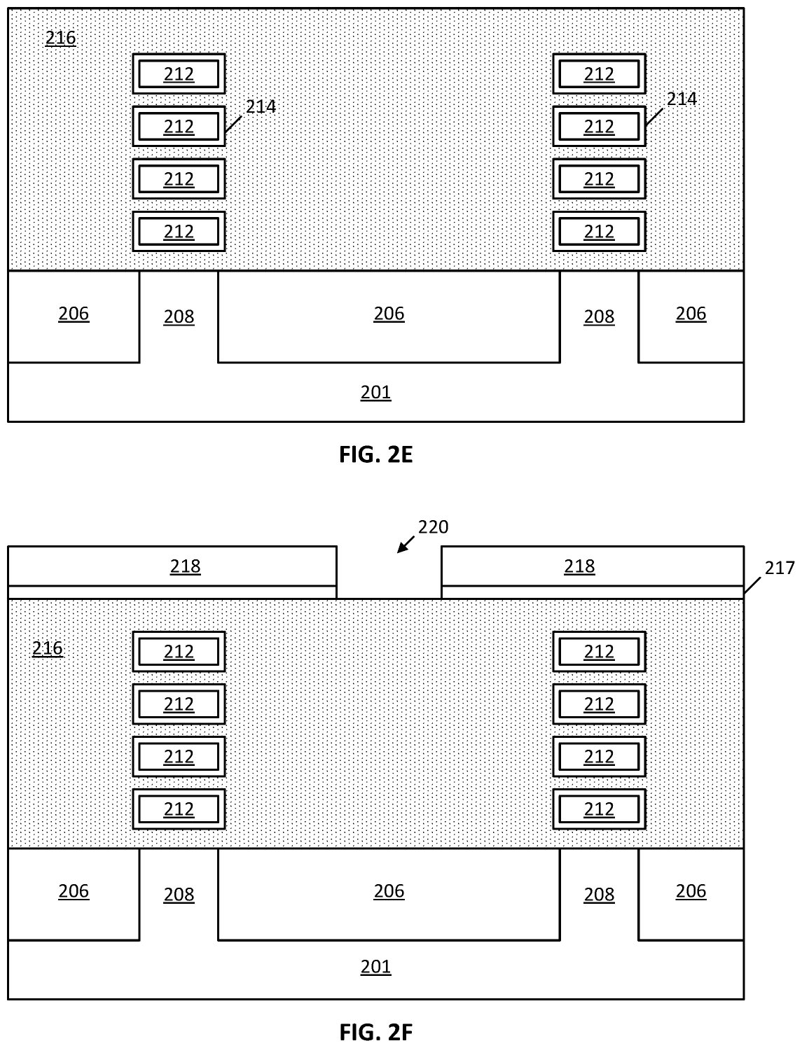

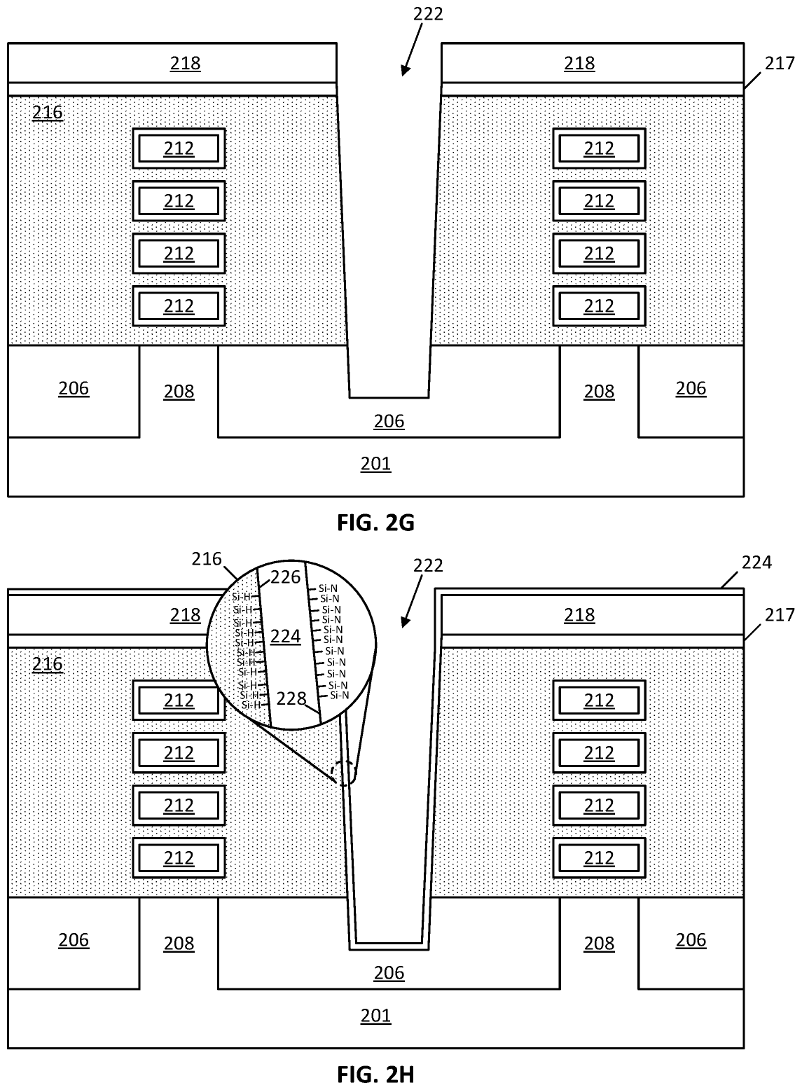

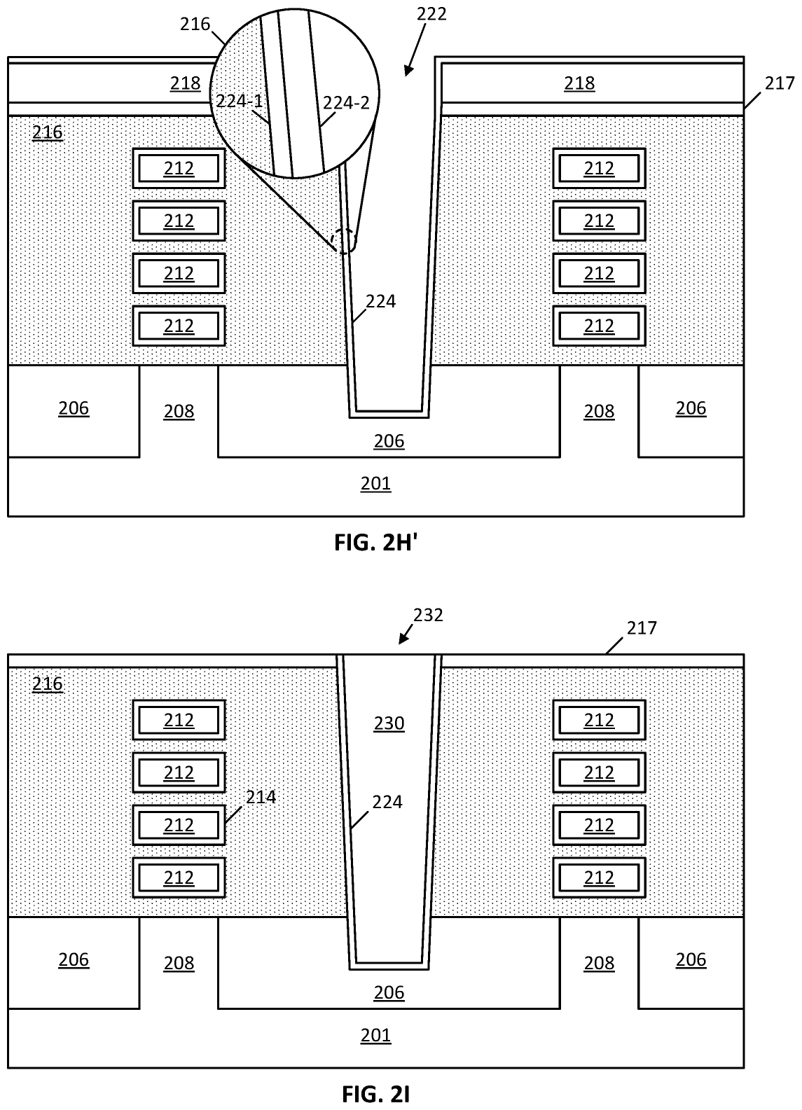

FIGS. 2A-2I include cross-sectional views that collectively illustrate an example process for forming an integrated circuit with semiconductor devices and one or more gate cuts having an improved liner structure, in accordance with an embodiment of the present disclosure. Each figure shows an example structure that results from the process flow up to that point in time, so the depicted structure evolves as the process flow continues, culminating in the structure shown in FIG. 2I, which is similar to the structure shown in FIG. 1A. The illustrated integrated circuit structure may be part of a larger integrated circuit that includes other integrated circuitry not depicted. Example materials and process parameters are given, but the present disclosure is not intended to be limited to any specific such materials or parameters, as will be appreciated. Although the fabrication of a single gate cut is illustrated in the aforementioned figures, it should be understood that any number of similar gate cuts can be fabricated across the integrated circuit using the same processes discussed herein.

FIG. 2A illustrates a cross-sectional view taken through a substrate 201 having a series of material layers formed over the substrate, according to an embodiment of the present disclosure. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201. The description above for substrate 102 applies equally to substrate 201.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

FIG. 2B depicts the cross-section view of the structure shown in FIG. 2A following the formation of a cap layer 205 and the subsequent formation of fins beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. The rows of fins extend lengthwise in a first direction (e.g., into and out of the page).

According to some embodiments, an anisotropic etching process through the layer stack continues into at least a portion of substrate 201. The etched portion of substrate 201 may be filled with a dielectric fill 206 that acts as shallow trench isolation (STI) between adjacent fins. Dielectric fill 206 may be any suitable dielectric material such as silicon dioxide. Subfin regions 208 represent remaining portions of substrate 201 between dielectric fill 206, according to some embodiments.

FIG. 2C depicts the cross-section view of the structure shown in FIG. 2B following the formation of a sacrificial gate 210 extending across the fins in a second direction different from the first direction, according to some embodiments. Sacrificial gate 210 may extend across the fins in a second direction that is orthogonal to the first direction. According to some embodiments, the sacrificial gate material is formed in parallel strips across the integrated circuit and removed in all areas not protected by a gate masking layer. Sacrificial gate 210 may be any suitable material that can be selectively removed without damaging the semiconductor material of the fins. In some examples, sacrificial gate 210 includes polysilicon. In some cases, sacrificial gate 210 may also include a gate dielectric, such as an oxide of the fin material.

Following the formation of sacrificial gate 210 (and prior to replacement of sacrificial gate 210 with a metal gate), additional semiconductor device structures are formed that are not shown in these cross-sections. These additional structures include spacer structures on the sidewalls of sacrificial gate 210 and source and drain regions on either ends of each of the fins. The formation of such structures can be accomplished using any number of processing techniques.

FIG. 2D depicts the cross-section view of the structure shown in FIG. 2C following the removal of sacrificial gate 210 and the removal of sacrificial layers 202, according to some embodiments. In examples where any gate masking layers are still present, they may also be removed at this time. Once sacrificial gate 210 is removed, the fins that had been beneath sacrificial gate 210 are exposed.

In the example where the fins include alternating semiconductor layers, sacrificial layers 202 are selectively removed to release nanoribbons 212 that extend between corresponding source or drain regions. Each vertical set of nanoribbons 212 represents the semiconductor or channel region of a different semiconductor device. It should be understood that nanoribbons 212 may also be nanowires or nanosheets (e.g., from a forksheet arrangement) or fins (e.g., for a finFET arrangement). Sacrificial gate 210 and sacrificial layers 202 may be removed using the same isotropic etching process or different isotropic etching processes.

FIG. 2E depicts the cross-section view of the structure shown in FIG. 2D following the formation of a gate structure and subsequent polishing, according to some embodiments. The gate structure includes a gate dielectric 214 and a conductive gate electrode 216. Gate dielectric 214 may be first formed around nanoribbons 212 prior to the formation of gate electrode 216. The gate dielectric 214 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 214 includes a layer of hafnium oxide with a thickness between about 1 nm and about 5 nm. In some embodiments, gate dielectric 214 may include one or more silicates (e.g., titanium silicate, tungsten silicate, niobium silicate, and silicates of other transition metals). In some cases, gate dielectric 214 may include a first layer on nanoribbons 212, and a second layer on the first layer. The first layer can be, for instance, an oxide of the semiconductor material of nanoribbons 212 (e.g., silicon dioxide) and the second layer can be a high-k dielectric material (e.g., hafnium oxide). More generally, gate dielectric 214 can include any number of dielectric layers. According to some embodiments, gate dielectric 214 forms along all surfaces exposed within the gate trench, such as along inner sidewalls of the spacer structures and along the top surfaces of dielectric fill 206 and subfin regions 208.

As noted above, gate electrode 216 can represent any number of conductive layers. The conductive gate electrode 216 may be deposited using electroplating, electroless plating, CVD, PECVD, ALD, or PVD, to name a few examples. In some embodiments, gate electrode 216 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 216 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structure, the entire structure may be polished or planarized such that the top surface of the gate structure (e.g., top surface of gate electrode 216) is planar with the top surface of other semiconductor elements, such as the spacer structures that define the gate trench.

FIG. 2F illustrates another cross-section view of the structure shown in FIG. 2E following the formation of a masking structure 218, according to some embodiments. In some examples, a gate cap 217 is formed prior to masking structure 218. Gate electrode 216 may be recessed within the gate trench and gate cap 217 may be formed within the recess above gate electrode 216 within the gate trench. Gate cap 217 may be a dielectric material, such as silicon nitride, for protecting the underlying gate electrode 216. In some examples, gate cap 217 has a thickness between about 10 nm and about 20 nm, such as around 15 nm.

Masking structure 218 may include any number of hard mask layers, such as any dielectric layers or carbon hard mask layers. An opening 220 may be formed through masking structure 218 and gate cap 217 to expose a portion of gate electrode 216 where a gate cut will be formed. A reactive ion etching (RIE) process may be used to form opening 220, according to some examples.

FIG. 2G illustrates another cross-section view of the structure shown in FIG. 2F following the formation of a gate cut recess 222 through at least an entire thickness of gate electrode 216, according to some embodiments. Gate cut recess 222 may have a high height-to-width aspect ratio of 5:1 or more, such as between 6:1 and 10:1 and may be formed via a series of RIE and passivation steps to etch through the conductive material of gate electrode 216. Gate cut recess 222 may be tapered and have a largest width along a top surface of gate electrode 216 between about 40 nm and about 50 nm. In some embodiments, gate cut recess 222 extends through an entire thickness of dielectric fill 206 and into the underlying substrate 201.

FIG. 2H illustrates another cross-section view of the structure shown in FIG. 2G following the formation of a dielectric liner 224 within gate cut recess 222, according to some embodiments. According to some embodiments, dielectric liner 224 includes a high-k dielectric material, such as silicon nitride, or any other material having a dielectric constant of at least 6.5. Dielectric liner 224 may be, for example, conformally deposited using ALD.

According to some embodiments, dielectric liner 224 is silicon nitride that is deposited in an environment without any nitrogen plasma (e.g., 100% argon plasma, for first several deposition cycles) to form a higher percentage of Si—H bonds compared to Si—N bonds at an interface 226 between dielectric liner 224 and gate electrode 216. The higher percentage of Si—H bonds at interface 226 provide better protection to the underlying gate electrode 216 from oxidation. According to some embodiments, an outer surface 228 of dielectric liner 224 includes a higher percentage of Si—N bonds compared to Si—H bonds. This may be achieved within a single deposited layer by slowly increasing or ramping the amount of nitrogen plasma in the deposition chamber to form an increasing gradient of Si—N bonds from interface 226 to outer surface 228. Correspondingly, dielectric layer 224 may also have a decreasing gradient of Si—H bonds from interface 226 to outer surface 228. The full thickness of dielectric liner 224 may be, for example, less than 5 nm, such as between 2 nm and 3 nm. In some such embodiments, a thickness of the portion of dielectric liner 224 having the higher percentage of Si—H bonds compared to Si—N bonds is between about 10 Å and about 15 Å. Other examples may have different dimensions and still achieve similar benefits.

In one example, dielectric liner 224 is deposited in a vacuum chamber with ammonia (NH3) at a flow rate between 1800 SCCM and 2400 SCCM and dichlorosilane (DCS) at a flow rate between 800 SCCM and 1200 SCCM in a pure (100%) argon plasma having a flow rate between 2500 SCCM and 3500 SCCM and at an RF power between 40 W and 60 W. The pure argon plasma produces a higher percentage of Si—H bonds compared to Si—N bonds. To increase the percentage of Si—N bonds, nitrogen plasma may be introduced up to a plasma containing about 5% nitrogen and 95% argon, according to some embodiments. In one example case, the first two to six deposition cycles (about one cycle per monolayer) are performed with argon-only, and then nitrogen is introduced gradually over the next two to twelve cycles. Table 1 shows one example deposition scheme.

TABLE 1
Graded Deposition of Dielectric Liner

| Cycle | Argon % | Nitrogen % |
|---|---|---|
| 1 | 100 | 0 |
| 2 | 100 | 0 |
| 3 | 100 | 0 |
| 4 | 99 | 1 |
| 5 | 98 | 2 |
| 6 | 96 | 4 |
| 7 | 95 | 5 |

As noted above, dielectric liner 224 may be a single deposited layer having a concentration gradient of Si—N or Si—H bonds across its thickness or dielectric liner 224 may represent multiple deposited dielectric layers having different concentrations of Si—N or Si—H bonds. FIG. 2H′ illustrates an example of dielectric liner 224 having a first sublayer 224-1 with a higher percentage of Si—H bonds compared to Si—N bonds and a second sublayer 224-2 with a higher percentage of Si—N bonds compared to Si—H bonds. First sublayer 224-1 is deposited directly on gate electrode 216 and second sublayer 224-2 is deposited on first sublayer 224-1, according to some embodiments. Although only two sublayers are illustrated, dielectric liner 224 may represent any number of sublayers with the first sublayer directly on gate electrode 216 having a highest percentage of Si—H bonds and a final deposited sublayer having a lowest percentage of Si—H bonds.

FIG. 2I illustrates another cross-section view of the structure shown in FIG. 2H following the formation of a dielectric fill 230 within a remaining volume of gate cut recess 222, according to some embodiments. Dielectric liner 224 and dielectric fill 230 together form a gate cut 232 extending through an entire thickness of the gate structure. Dielectric fill 230 may be formed directly on dielectric liner 224. According to some embodiments, dielectric fill 230 includes a medium-to-low-k dielectric material, such as silicon dioxide or flowable oxide or porous oxide or any other material having a dielectric constant of 4.5 or lower, including one or more airgaps having a local dielectric constant of 1.0, to lower the overall or global dielectric constant of the dielectric gate cut structure. Dielectric fill 230 may be deposited using any suitable plasma deposition technique, such as CVD. In still other example embodiments, dielectric fill 230 may be conformally deposited using ALD or CVD so as to pinch-off and close at the narrow portion toward the bottom of gate cut recess 222. In some embodiments, dielectric fill 230 pinches off at the top of gate cut recess 222 such that an airgap is formed within a central area of gate cut 232.

Dielectric fill 230 may overflow out of gate cut recess 222 and be polished back using chemical mechanical polishing (CMP), according to some embodiments. In the illustrated example, dielectric fill 230 is polished back to be substantially level with a top surface of gate cap 217. Because gate cut 232 is formed through the gate structure (rather than being formed before it), gate dielectric 214 does not extend up any sidewall of gate cut 232.

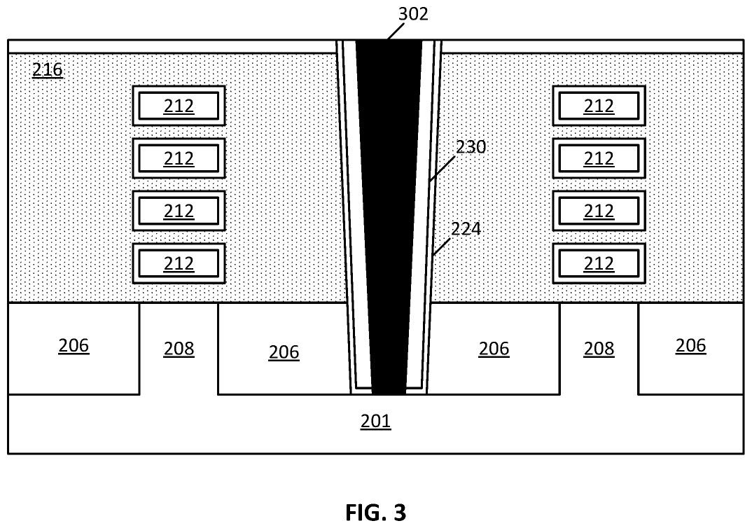

FIG. 3 illustrates another example of a gate cut formed using the process described in FIGS. 2A-21 that is used to provide isolation for a conductive via 302, according to some embodiments. Conductive via 302 may be formed through a central portion of the gate cut, such as through a central axis of the gate cut that extends along the height of the gate cut in the third direction. In some embodiments, conductive via 302 is formed through the entire height of dielectric fill 230. Conductive via 302 may also punch through a bottom portion of dielectric liner 224. Conductive via 302 may include any suitable conductive material, such as tungsten, ruthenium, molybdenum, or cobalt. In some embodiments, conductive via 302 includes a liner or barrier layer directly on the inner walls of the gate cut and a conductive fill material on the liner or barrier layer. The liner or barrier layer may include, for example, nitrogen along with tantalum or titanium, or other suitable liner or barrier materials. Such liner/barrier materials are particularly useful with respect to fill materials such as copper, which can migrate into neighboring dielectric materials during subsequent processing and thus change the desired dielectric constant of those dielectric materials.

Conductive via 302 may be provided to contact backside structures formed during subsequent processing. For example, in some embodiments, substrate 201 may be removed from the backside (e.g., via a CMP process), thus exposing a bottom surface of conductive via 302. A backside layer of dielectric material (e.g., silicon dioxide) may then be deposited, and one or more conductive structures may then be formed on the backside and contacting conductive via 302. More generally, frontside and backside interconnect structures each having one or more interconnect layers (not shown) may be present, and conductive via 302 can be used to couple one or more frontside interconnect features to one or more backside interconnect features. The frontside interconnect structure can be formed, for instance, during standard backend of line (BEOL) processing, and the backside interconnect structure can be subsequently formed after removal of substrate 201 during backside processing. In some such embodiments, backside processing may include replacing subfin regions 208 with one or more dielectric layers. In any such example cases, the presence of dielectric fill 230 may help to reduce parasitic capacitance between conductive via 302 and gate electrode 216.

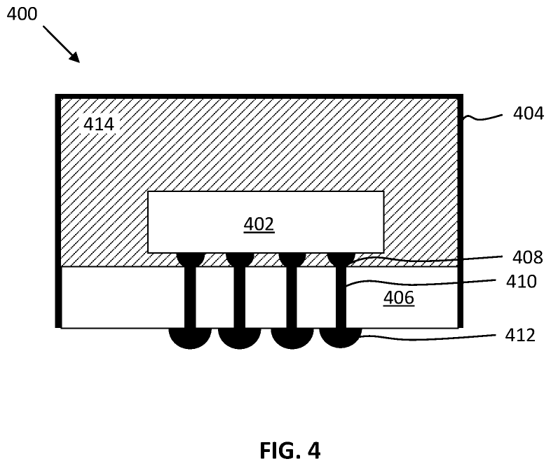

FIG. 4 illustrates an example embodiment of a chip package 400, in accordance with an embodiment of the present disclosure. As can be seen, chip package 400 includes one or more dies 402. One or more dies 402 may include at least one integrated circuit having semiconductor devices, such as any of the semiconductor devices disclosed herein. One or more dies 402 may include any other circuitry used to interface with other devices formed on the dies, or other devices connected to chip package 400, in some example configurations.

As can be further seen, chip package 400 includes a housing 404 that is bonded to a package substrate 406. The housing 404 may be any standard or proprietary housing, and may provide, for example, electromagnetic shielding and environmental protection for the components of chip package 400. The one or more dies 402 may be conductively coupled to a package substrate 406 using connections 408, which may be implemented with any number of standard or proprietary connection mechanisms, such as solder bumps, ball grid array (BGA), pins, or wire bonds, to name a few examples. Package substrate 406 may be any standard or proprietary package substrate, but in some cases includes a dielectric material having conductive pathways (e.g., including conductive vias and lines) extending through the dielectric material between the faces of package substrate 406, or between different locations on each face. In some embodiments, package substrate 406 may have a thickness less than 1 millimeter (e.g., between 0.1 millimeters and 0.5 millimeters), although any number of package geometries can be used. Additional conductive contacts 412 may be disposed at an opposite face of package substrate 406 for conductively contacting, for instance, a printed circuit board (PCB). One or more vias 410 extend through a thickness of package substrate 406 to provide conductive pathways between one or more of connections 408 to one or more of contacts 412. Vias 410 are illustrated as single straight columns through package substrate 406 for ease of illustration, although other configurations can be used (e.g., damascene, dual damascene, through-silicon via, or an interconnect structure that meanders through the thickness of substrate 406 to contact one or more intermediate locations therein). In still other embodiments, vias 410 are fabricated by multiple smaller stacked vias, or are staggered at different locations across package substrate 406. In the illustrated embodiment, contacts 412 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 412, to inhibit shorting.

In some embodiments, a mold material 414 may be disposed around the one or more dies 402 included within housing 404 (e.g., between dies 402 and package substrate 406 as an underfill material, as well as between dies 402 and housing 404 as an overfill material). Although the dimensions and qualities of the mold material 414 can vary from one embodiment to the next, in some embodiments, a thickness of mold material 414 is less than 1 millimeter. Example materials that may be used for mold material 414 include epoxy mold materials, as suitable. In some cases, the mold material 414 is thermally conductive, in addition to being electrically insulating.

### Methodology

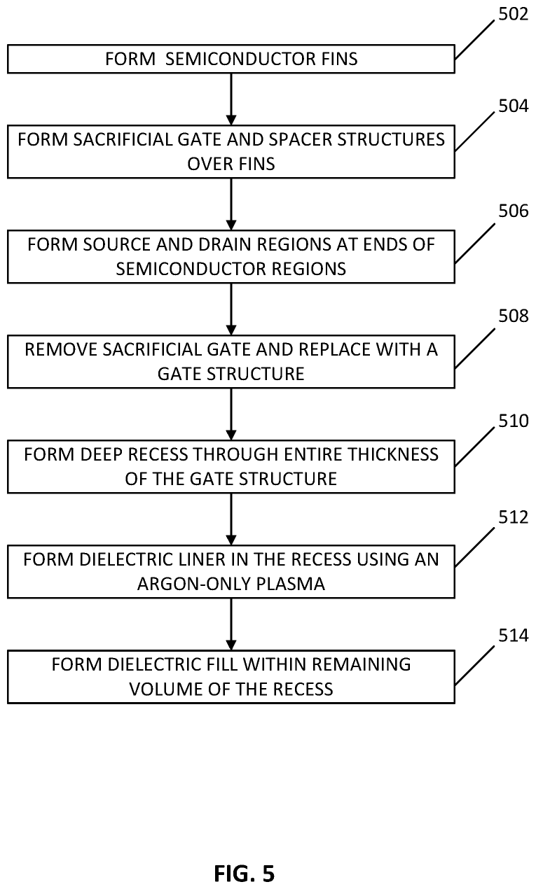

FIG. 5 is a flow chart of a method 500 for forming at least a portion of an integrated circuit, according to an embodiment. Various operations of method 500 may be illustrated in FIGS. 2A-21. However, the correlation of the various operations of method 500 to the specific components illustrated in the aforementioned figures is not intended to imply any structural and/or use limitations. Rather, the aforementioned figures provide one example embodiment of method 500. Other operations may be performed before, during, or after any of the operations of method 500. For example, method 500 does not explicitly describe all processes that are performed to form common transistor structures. Some of the operations of method 500 may be performed in a different order than the illustrated order.

Method 500 begins with operation 502 where any number of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of the one or more fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 500 continues with operation 504 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 500 continues with operation 506 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 500 continues with operation 508 where the sacrificial gate is removed and replaced with a gate structure. The sacrificial gate may be removed using an isotropic etching process that selectively removes all of the material from the sacrificial gate, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples. In some embodiments, the gate electrode may be recessed, and a dielectric gate cap is formed within the recessed area. The dielectric gate cap may have a thickness, for instance, between 10 nm and 20 nm, such as around 15 nm.

Method 500 continues with operation 510 where a deep recess is formed through an entire thickness of the gate structure. A mask structure may be formed over the gate structure and an opening may be formed through the mask structure to expose a portion of the underlying gate electrode. According to some embodiments, the opening through the mask structure is at a location where the deep recess is to be formed through the underlying gate electrode. The mask structure may include any number of hard mask layers, such as any dielectric layers or carbon hard mask layers. The opening may be formed using a directional RIE process. According to some embodiments, the deep recess has a high height-to-width aspect ratio of at least 6:1 and extends through at least an entire thickness of the gate structure. In some examples, the deep recess also extends through an entire thickness of the dielectric fill between devices and into the underlying substrate.

Method 500 continues with operation 512 where a dielectric liner is formed within the recess and on the exposed sidewalls of the gate electrode. According to some embodiments, the dielectric liner includes a high-k dielectric material, such as silicon nitride, that is deposited using a pure argon plasma (e.g., no percentage of nitrogen plasma). In one example, the dielectric liner is conformally deposited via ALD in a vacuum chamber with ammonia (NH3) at a flow rate between 1800 SCCM and 2400 SCCM and dichlorosilane (DCS) at a flow rate between 800 SCCM and 1200 SCCM in a pure (100%) argon plasma having a flow rate between 2500 SCCM and 3500 SCCM and at an RF power between 40 W and 60 W. The pure argon plasma produces a higher percentage of Si—H bonds compared to Si—N bonds. To increase the percentage of Si—N bonds, nitrogen plasma may be introduced up to a plasma containing about 5% nitrogen and 95% argon, according to some embodiments.

In any case, the percentage of Si—H bonds is higher compared to the percentage of Si—N bonds at the interface between the deposited dielectric liner and the gate electrode along the sidewalls of the deep recess. The dielectric layer may include an increasing gradient of Si—N bonds through the thickness of the layer moving away from the interface at the gate electrode. In some examples, the outer surface of the deposited dielectric liner has a higher percentage of Si—N bonds compared to Si—H bonds. In some other embodiments, the dielectric liner represents any number of deposited silicon nitride sublayers with each sublayer being deposited with a different nitrogen plasma concentration to produce a different percentage of Si—N bonds compared to Si—H bonds. For example, a first deposited sublayer may have a highest concentration of Si—H bonds (or a lowest concentration of Si—N bonds) amongst the stack of sublayers, and a final deposited sublayer may have a lowest concentration of Si—H bonds (or a highest concentration of Si—N bonds) amongst the stack of sublayers. In some such cases, there are one or more intervening layers, each having progressively lower concentration of Si—H bonds as their respective distance from the gate electrode increases.

Method 500 continues with operation 514 where a dielectric fill is formed within the recess and on the dielectric liner. According to some embodiments, the dielectric fill includes a medium-to-low-k dielectric material, such as silicon dioxide or flowable oxide or any other material having a dielectric constant of 4.5 or lower, as described above. The dielectric fill may be polished back until a top surface of the dielectric fill is level with a top surface of the mask structure or with a top surface of the dielectric gate cap on the gate electrode. The interface between the dielectric fill and the underlying dielectric liner may exhibit a higher percentage of Si—N bonds compared to Si—H bonds.

### Example System

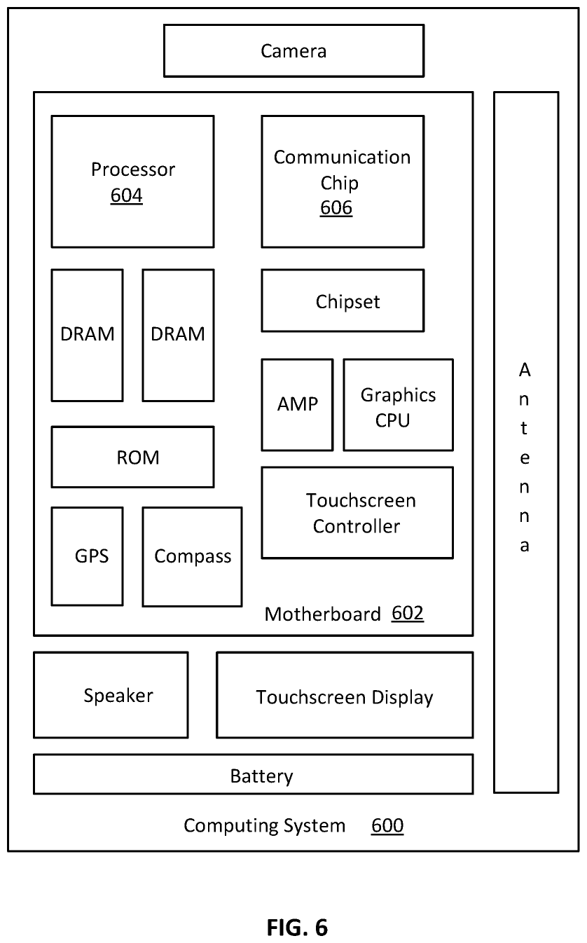

FIG. 6 is an example computing system implemented with one or more of the integrated circuit structures as disclosed herein, in accordance with some embodiments of the present disclosure. As can be seen, the computing system 600 houses a motherboard 602. The motherboard 602 may include a number of components, including, but not limited to, a processor 604 and at least one communication chip 606, each of which can be physically and electrically coupled to the motherboard 602, or otherwise integrated therein. As will be appreciated, the motherboard 602 may be, for example, any printed circuit board (PCB), whether a main board, a daughterboard mounted on a main board, or the only board of system 600, etc.

Depending on its applications, computing system 600 may include one or more other components that may or may not be physically and electrically coupled to the motherboard 602. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 600 may include one or more integrated circuit structures or devices configured in accordance with an example embodiment, such as a module including an integrated circuit on a substrate, the substrate having semiconductor devices and at least one gate cut having an improved dielectric liner to protect the gate metal from oxidation. In some embodiments, multiple functions can be integrated into one or more chips (e.g., for instance, note that the communication chip 606 can be part of or otherwise integrated into the processor 604).

The communication chip 606 enables wireless communications for the transfer of data to and from the computing system 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing system 600 includes an integrated circuit die packaged within the processor 604. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 606 also may include an integrated circuit die packaged within the communication chip 606. In accordance with some such example embodiments, the integrated circuit die of the communication chip includes one or more semiconductor devices as variously described herein. As will be appreciated in light of this disclosure, note that multi-standard wireless capability may be integrated directly into the processor 604 (e.g., where functionality of any chips 606 is integrated into processor 604, rather than having separate communication chips). Further note that processor 604 may be a chip set having such wireless capability. In short, any number of processor 604 and/or communication chips 606 can be used. Likewise, any one chip or chip set can have multiple functions integrated therein.

In various implementations, the computing system 600 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 600 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.
Example 1 is an integrated circuit that includes a semiconductor device having a semiconductor region extending in a first direction from a source or drain region and a gate structure extending in a second direction over the semiconductor region, and a dielectric structure adjacent to the semiconductor region and extending across the gate structure in the first direction and through an entire thickness of the gate structure in a third direction. The dielectric structure includes a dielectric layer along edges of the dielectric structure and a dielectric fill on the dielectric layer. The dielectric layer includes a higher percentage of hydrogen atoms compared to nitrogen atoms at an interface between the dielectric layer and the gate structure.
Example 2 includes the integrated circuit of Example 1, wherein the dielectric layer comprises silicon and nitrogen.
Example 3 includes the integrated circuit of Example 1 or 2, wherein the dielectric layer has a thickness between about 2 nm and about 3 nm.
Example 4 includes the integrated circuit of any one of Examples 1-3, wherein the dielectric fill comprises silicon and oxygen.
Example 5 includes the integrated circuit of any one of Examples 1-4, wherein the dielectric layer comprises a higher percentage of nitrogen atoms compared to hydrogen atoms at an interface between the dielectric layer and the dielectric fill.
Example 6 includes the integrated circuit of Example 5, wherein the dielectric layer has a decreasing gradient of hydrogen atoms from the interface between the dielectric layer and the gate structure to the interface between the dielectric layer and the dielectric fill.
Example 7 includes the integrated circuit of Example 5, wherein the dielectric layer comprises a first sublayer having the higher percentage of hydrogen atoms compared to nitrogen atoms on the gate structure and a second sublayer on the first sublayer, the second sublayer having the higher percentage of nitrogen atoms compared to hydrogen atoms.
Example 8 includes the integrated circuit of any one of Examples 1-7, wherein the dielectric layer has a higher dielectric constant than the dielectric fill.
Example 9 includes the integrated circuit of any one of Examples 1-8, wherein the semiconductor region comprises a plurality of semiconductor nanoribbons.
Example 10 includes the integrated circuit of Example 9, wherein the plurality of semiconductor nanoribbons comprise germanium, silicon, or a combination thereof.
Example 11 includes the integrated circuit of any one of Examples 1-10, wherein the gate structure includes a gate dielectric around the semiconductor region, and a gate electrode, the gate dielectric between the semiconductor region and the gate electrode.
Example 12 includes the integrated circuit of Example 11, wherein the gate dielectric is not present on any sidewall of the dielectric structure.
Example 13 includes the integrated circuit of any one of Examples 1-12, further comprising a conductive via extending in the third direction through the dielectric structure.
Example 14 is a printed circuit board comprising the integrated circuit of any one of Examples 1-13.
Example 15 is an electronic device that includes a chip package having one or more dies. At least one of the one or more dies includes a semiconductor region extending in a first direction from a source or drain region, a gate structure extending in a second direction over the semiconductor region, and a dielectric structure adjacent to the semiconductor region and extending across the gate structure in the first direction and through an entire thickness of the gate structure in a third direction. The dielectric structure includes a dielectric layer along edges of the dielectric structure and a dielectric fill on the dielectric layer. The dielectric layer includes a higher percentage of Si—H bonds compared to Si—N bonds at an interface between the dielectric layer and the gate structure.
Example 16 includes the electronic device of Example 15, wherein the dielectric layer comprises silicon and nitrogen.
Example 17 includes the electronic device of Example 15 or 16, wherein the dielectric layer has a thickness between about 2 nm and about 3 nm.
Example 18 includes the electronic device of any one of Examples 15-17, wherein the dielectric fill comprises silicon and oxygen.
Example 19 includes the electronic device of any one of Examples 15-18, wherein the dielectric layer comprises a higher percentage of Si—N bonds compared to Si—H bonds at an interface between the dielectric layer and the dielectric fill.
Example 20 includes the electronic device of Example 19, wherein the dielectric layer has a decreasing gradient of Si—H bonds from the interface between the dielectric layer and the gate structure to the interface between the dielectric layer and the dielectric fill.
Example 21 includes the electronic device of Example 19, wherein the dielectric layer comprises a first sublayer having the higher percentage of Si—H bonds compared to Si—N bonds on the gate structure and a second sublayer on the first sublayer, the second sublayer having the higher percentage of Si—N bonds compared to Si—H bonds.
Example 22 includes the electronic device of any one of Examples 15-21, wherein the dielectric layer has a higher dielectric constant than the dielectric fill.
Example 23 includes the electronic device of any one of Examples 15-22, wherein the semiconductor region comprises a plurality of semiconductor nanoribbons.
Example 24 includes the electronic device of Example 23, wherein the plurality of semiconductor nanoribbons comprise germanium, silicon, or a combination thereof.
Example 25 includes the electronic device of any one of Examples 15-24, wherein the gate structure includes a gate dielectric around the semiconductor region.
Example 26 includes the electronic device of Example 25, wherein the gate dielectric is not present on any sidewall of the dielectric structure.
Example 27 includes the electronic device of any one of Examples 15-26, wherein the at least one of the one or more dies further comprises a conductive via extending in the third direction through the dielectric structure.
Example 28 includes the electronic device of any one of Examples 15-27, further comprising a printed circuit board, wherein the chip package is coupled to the printed circuit board.
Example 29 is a method of forming an integrated circuit. The method includes forming a fin comprising semiconductor material, the fin extending above a substrate and extending in a first direction; forming a gate electrode extending over the semiconductor material in a second direction different from the first direction; forming a recess extending in a third direction through an entire thickness of the gate electrode adjacent to the fin; forming a dielectric layer within the recess such that the dielectric layer includes a higher percentage of Si—H bonds compared to Si—N bonds at an interface between the dielectric layer and the gate electrode; and forming a dielectric fill within a remaining volume of the recess and on the dielectric layer.
Example 30 includes the method of Example 29, further comprising forming a conductive via extending through an entire thickness of the dielectric fill in the third direction.
Example 31 includes the method of Example 29 or 30, further comprising forming source and drain regions at ends of the semiconductor material.
Example 32 includes the method of any one of Examples 29-31, wherein forming the dielectric layer comprises depositing a material layer comprising silicon and nitrogen using a 100% argon plasma.
Example 33 includes the method of any one of Examples 29-31, wherein forming the dielectric layer comprises depositing a first sublayer comprising silicon and nitrogen using a 100% argon plasma and depositing a second sublayer using a plasma that contains up to 5% nitrogen, the second sublayer being over the first sublayer.
Example 34 includes the method of Example 33, wherein the second sublayer includes a higher percentage of Si—N bonds compared to Si—H bonds at an interface between the second sublayer and the dielectric fill.
Example 35 includes the method of any one of Examples 29-31, wherein forming the dielectric layer comprises depositing the dielectric layer using an argon plasma with an increasing percentage of nitrogen as the dielectric layer is deposited.
Example 36 is an integrated circuit that includes a first semiconductor device having a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, and a dielectric structure extending in the first direction between the first gate structure and the second gate structure and through an entire thickness of the first and second gate structures in a third direction. The dielectric structure includes a dielectric layer along edges of the dielectric structure, and a dielectric fill on the dielectric layer. The dielectric layer includes a higher percentage of hydrogen atoms compared to nitrogen atoms at an interface between the dielectric layer and the first gate structure and at an interface between the dielectric layer and the second gate structure.
Example 37 includes the integrated circuit of Example 36, wherein the dielectric layer comprises silicon and nitrogen.
Example 38 includes the integrated circuit of Example 36 or 37, wherein the dielectric layer has a thickness between about 2 nm and about 3 nm.
Example 39 includes the integrated circuit of any one of Examples 36-38, wherein the dielectric fill comprises silicon and oxygen.
Example 40 includes the integrated circuit of any one of Examples 36-39, wherein the dielectric layer comprises a higher percentage of nitrogen atoms compared to hydrogen atoms at an interface between the dielectric layer and the dielectric fill.
Example 41 includes the integrated circuit of Example 40, wherein the dielectric layer has a decreasing gradient of hydrogen atoms from the interface between the dielectric layer and the first gate structure to the interface between the dielectric layer and the dielectric fill and from the interface between the dielectric layer and the second gate structure to the interface between the dielectric layer and the dielectric fill.
Example 42 includes the integrated circuit of Example 40, wherein the dielectric layer comprises a first sublayer having the higher percentage of hydrogen atoms compared to nitrogen atoms on the first and second gate structures and a second sublayer on the first sublayer, the second sublayer having the higher percentage of nitrogen atoms compared to hydrogen atoms.
Example 43 includes the integrated circuit of any one of Examples 36-42, wherein the dielectric layer has a higher dielectric constant than the dielectric fill.
Example 44 includes the integrated circuit of any one of Examples 36-42, wherein the first semiconductor region comprises a first plurality of semiconductor nanoribbons and the second semiconductor region comprises a second plurality of semiconductor nanoribbons.
Example 45 includes the integrated circuit of Example 44, wherein the first plurality of semiconductor nanoribbons and the second plurality of semiconductor nanoribbons comprise germanium, silicon, or a combination thereof.
Example 46 includes the integrated circuit of any one of Examples 36-45, wherein the first gate structure includes a first gate dielectric around the first semiconductor region and the second gate structure includes a second gate dielectric around the second semiconductor region.
Example 47 includes the integrated circuit of Example 46, wherein the first gate dielectric and the second gate dielectric are not present on any sidewall of the dielectric structure.
Example 48 includes the integrated circuit of any one of Examples 36-47, further comprising a conductive via extending in the third direction through the dielectric structure.
Example 49 is a printed circuit board comprising the integrated circuit of any one of Examples 36-48.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a source or drain region, and a gate structure extending in a second direction over the semiconductor region; and
a dielectric structure adjacent to the semiconductor region and extending across the gate structure in the first direction and through an entire thickness of the gate structure in a third direction, the dielectric structure comprising a dielectric layer along edges of the dielectric structure, and
a dielectric fill between portions of the dielectric layer,
wherein the dielectric layer comprises a higher percentage of hydrogen atoms compared to nitrogen atoms at an interface between the dielectric layer and the gate structure.

2. The integrated circuit of claim 1, wherein the dielectric layer has a thickness between about 2 nm and about 3 nm.

3. The integrated circuit of claim 1, wherein the dielectric layer comprises a higher percentage of nitrogen atoms compared to hydrogen atoms at an interface between the dielectric layer and the dielectric fill.

4. The integrated circuit of claim 3, wherein the dielectric layer has a decreasing gradient of hydrogen atoms from the interface between the dielectric layer and the gate structure to the interface between the dielectric layer and the dielectric fill.

5. The integrated circuit of claim 3, wherein the dielectric layer comprises a first sublayer having the higher percentage of hydrogen atoms compared to nitrogen atoms on the gate structure and a second sublayer on the first sublayer, the second sublayer having the higher percentage of nitrogen atoms compared to hydrogen atoms.

6. The integrated circuit of claim 1, wherein the gate structure includes a gate dielectric around the semiconductor region, and a gate electrode, the gate dielectric between the semiconductor region and the gate electrode, wherein the gate dielectric is not present on any sidewall of the dielectric structure.

7. The integrated circuit of claim 1, further comprising a conductive via extending in the third direction through the dielectric structure.

8. A printed circuit board comprising the integrated circuit of claim 1.

9. An electronic device, comprising:
a chip package comprising one or more dies, at least one of the one or more dies comprising
a semiconductor region extending in a first direction from a source or drain region;
a gate structure extending in a second direction over the semiconductor region; and
a dielectric structure adjacent to the semiconductor region and extending across the gate structure in the first direction and through an entire thickness of the gate structure in a third direction, the dielectric structure comprising a dielectric layer along edges of the dielectric structure, and
a dielectric fill on the dielectric layer,
wherein the dielectric layer comprises a higher percentage of Si—H bonds compared to Si—N bonds at an interface between the dielectric layer and the gate structure.

10. The electronic device of claim 9, wherein the dielectric layer comprises a higher percentage of Si—N bonds compared to Si—H bonds at an interface between the dielectric layer and the dielectric fill.

11. The electronic device of claim 10, wherein the dielectric layer has a decreasing gradient of Si—H bonds from the interface between the dielectric layer and the gate structure to the interface between the dielectric layer and the dielectric fill.

12. The electronic device of claim 10, wherein the dielectric layer comprises a first sublayer having the higher percentage of Si—H bonds compared to Si—N bonds on the gate structure and a second sublayer on the first sublayer, the second sublayer having the higher percentage of Si—N bonds compared to Si—H bonds.

13. The electronic device of claim 9, wherein the dielectric layer has a higher dielectric constant than the dielectric fill.

14. The electronic device of claim 9, wherein the at least one of the one or more dies further comprises a conductive via extending in the third direction through the dielectric structure.

15. An integrated circuit comprising:
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region; and
a dielectric structure extending in the first direction between the first gate structure and the second gate structure and through an entire thickness of the first and second gate structures in a third direction, the dielectric structure comprising
a dielectric layer along edges of the dielectric structure, and
a dielectric fill on the dielectric layer,
wherein the dielectric layer comprises a higher percentage of hydrogen atoms compared to nitrogen atoms at an interface between the dielectric layer and the first gate structure and at an interface between the dielectric layer and the second gate structure.

16. The integrated circuit of claim 15, wherein the dielectric layer comprises a higher percentage of nitrogen atoms compared to hydrogen atoms at an interface between the dielectric layer and the dielectric fill.

17. The integrated circuit of claim 16, wherein the dielectric layer has a decreasing gradient of hydrogen atoms from the interface between the dielectric layer and the first gate structure to the interface between the dielectric layer and the dielectric fill and from the interface between the dielectric layer and the second gate structure to the interface between the dielectric layer and the dielectric fill.

18. The integrated circuit of claim 16, wherein the dielectric layer comprises a first sublayer having the higher percentage of hydrogen atoms compared to nitrogen atoms on the first and second gate structures and a second sublayer on the first sublayer, the second sublayer having the higher percentage of nitrogen atoms compared to hydrogen atoms.

19. The integrated circuit of claim 15, wherein the first gate structure includes a first gate dielectric around the first semiconductor region and the second gate structure includes a second gate dielectric around the second semiconductor region, wherein the first gate dielectric and the second gate dielectric are not present on any sidewall of the dielectric structure.

20. The integrated circuit of claim 15, further comprising a conductive via extending in the third direction through the dielectric structure.
